(19) United States
(12) Patent Application Publication
(10) Pub. No.: US 2006/0214706 A1
(43) Pub. Date: Sep. 28, 2006

(54) Reduced phase noise frequency divider

(76) Inventor: Robert E. Temple, Greenacres, WA (US)

Correspondence Address: AGILENT TECHNOLOGIES INC.;INTELLECTUAL PROPERTY ADMINISTRATION, LEGAL DEPT,, M/S DU404, P.O. BOX 7599, LOVELAND, CO, 80537-0599, US

(21) Appl. No.: 11/090,525

(22) Filed: Mar. 25, 2005

(51) Int. Cl. H03B 19/00

(52) U.S. Cl. 327/117

(57) ABSTRACT

A frequency divider with reduced phase noise accepts a single-ended signal, converts it to a differential signal, and processes the differential signal through a series of dividers. The differential output of the divider chain is fed to a differential limiting amplifier which produces the output. The single-ended to differential input signal conversion may be accomplished by a separate stage, or by the first divider stage

### TECHNICAL FIELD

Embodiments in accordance with the invention are related to frequency dividers, and particularly to reduced phase noise dividers.

### BACKGROUND

An ideal signal source generating a single frequency should produce a sine wave output. Mathematically, such an output would be described as:
V(t)=V₀ sin 2πf₀t
where V₀ is the nominal amplitude and f₀ is the nominal frequency. Unfortunately, such signal sources are not realizable. Actual signals are better described mathematically as:
V(t)=(V₀+ε(t)) sin (2πf₀t+Δφ(t))
where ε(t) represents amplitude fluctuations versus time, and Δφ(t) represents phase fluctuations versus time.

The time varying quantities, ε(t) and Δφ(t), can be broken into two components, spurious signals and noise. Spurious signals, also called spurs, are discrete signals appearing as distinct spectral lines in a spectral density plot. These signals are usually related to known phenomena such as unwanted mixer products, leakage of other signals, and the like. Noise is random in nature. Sources of random sideband noise in a signal. source such as an oscillator include thermal noise, shot noise, and flicker noise in the components making up the source. A signal source such as a phase-locked-loop digital synthesizer will typically contain both components in it's amplitude modulated (AM) and phase modulated (PM) spectra.

Phase noise in a signal may be measured and described as the ratio of the power at an offset f Hertz away from the carrier frequency to the power at the carrier frequency. This measurement is known in the art as L(f).

A common approach to reducing phase noise from a signal source is to divide the signal down, commonly by a power of two such as 2, 4, 16, or 256 for example. An ideal divider should reduce phase noise 6 dB per octave, and of course, not introduce any noise itself.

Unfortunately, ideal dividers are not realizable. Non-ideal dividers introduce noise into the signal they are processing.

### SUMMARY OF THE INVENTION

A frequency divider with reduced phase noise converts a single-ended electrical input signal to differential form, feeds the differential signal to one or more differential frequency dividers, and finally to a differential limiting amplifier. The input stage of one of the frequency dividers may be used for the single-ended to differential signal conversion.

### BRIEF DESCRIPTION OF THE DRAWINGS

FIG. 1 shows a block diagram of a divider according to the present invention, and

FIG. 2 shows a phase noise plot.

### DETAILED DESCRIPTION

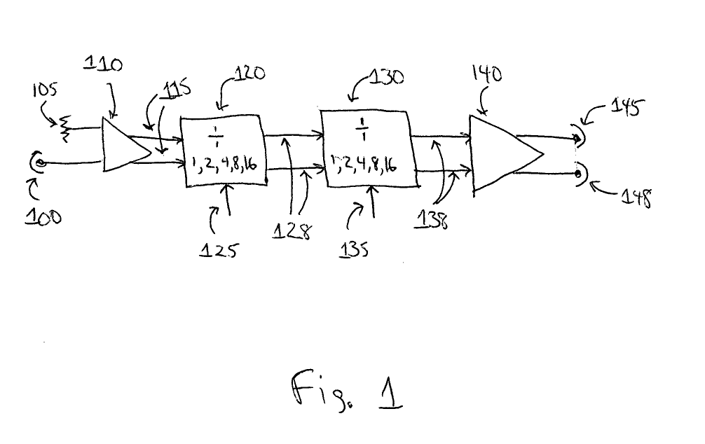

FIG. 1 shows a block diagram of a divider according to the present invention. For clarity, power supplies, bypassing, and the like are not shown. The signal to be divided is connected to input 100, which feeds input stage 110. While this stage may provide preamplification, its primary purpose is to convert the single-ended input signal at input 100 to a differential signal 115. This is accomplished using standard ECL (Emitter Coupled Logic) or similar topologies; terminator 105 provides proper termination for the other input of input stage 110. Differential signal 115 feeds the input of divider block 120. A single divider block may be used, or multiple blocks may be used to achieve the desired divide ratios. The output 138 of second divider block 130 feeds differential limiting amplifier 140. The complimentary outputs of differential limiting amplifier 140 are provided at 145 and 148.

Input stage 110 may be a separate stage, or it may be a part of divider 120. In achieving the best noise performance, it is important to provide a low phase-noise signal to input 100. Many signal sources achieve their lowest noise levels at their highest output power. It may be necessary to use an attenuator between the signal source and input 100 to stay within the signal handling range of input stage 110. In the embodiment shown, the maximum signal input level is on the order of +6 dBm.

Divider blocks 120 and 130 contain flip-flop dividers plus selection circuitry responsive to select inputs 125 and 135 which select divide ratios of 1 (pass-through), 2, 4, 8, or 16, corresponding to one, two, three, or four divide stages internal to the divider block. Other divider configurations are also possible, so long as the final divide stage is a divide-by-two, providing an output signal with a 50% duty cycle. As an example, an arbitrary divide-by-N block could be followed by a divide-by-two. With two such divider blocks in series, divide ratios in powers of two up to 256 may be achieved. Fully differential ECL topologies are used in the signal paths of divide blocks 120 and 130.

In the embodiment shown, input stage 110 and divider blocks 120 and 130 are constructed using Gallium Arsenide heterojunction bipolar transistors (GaAs HBT), and typically demonstrate performance up to 15 GHz. Other ECL families or similar forms of current-mode logic may be used if this frequency range is not needed.

Differential limiting amplifier 140 takes differential output 138 of divider stage 130 and produces complimentary (differential) outputs 145 and 148. Only one output may be used, or both outputs may be used, providing a differential output, or two complimentary outputs. A limiting amplifier takes an input signal and provides an output signal with a full-range voltage swing given a wide range of inputs. In the embodiment shown, a differential limiting amplifier using GaAs HBT transistors and having a single-ended gain of about 28 dB and a maximum frequency response of 15 GHz was used.

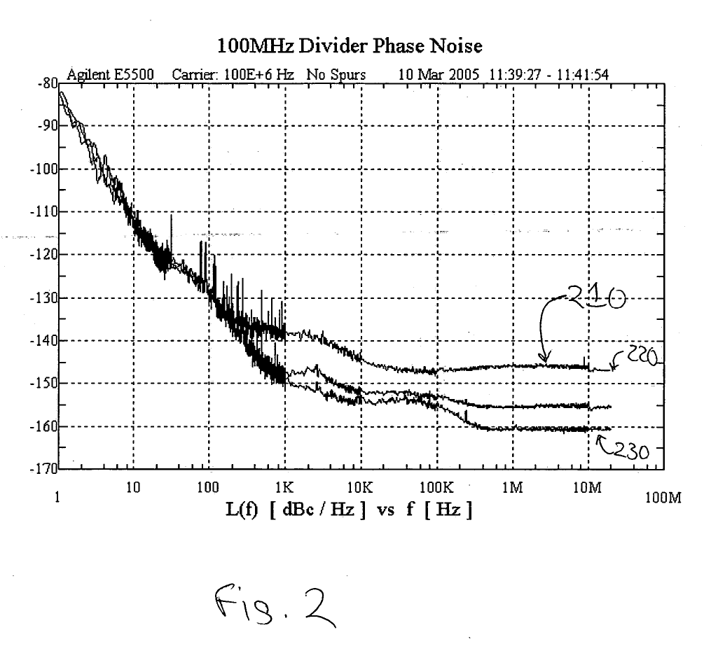

FIG. 2 shows a phase noise plot comparing the phase noise response of current dividers with the phase noise response of a divider according to the present invention. The measurements of FIG. 1 were made with an Agilent Technologies E5500A Phase Noise Measurement System. The E5500A has a typical noise floor of −180 dBc/Hz.

Practitioners of the electronic arts will appreciate that in making measurements at these low noise levels, and designing equipment to achieve these low noise levels, careful attention must be given to circuit board layout including characteristic impedance of signal lines, adequate grounding and shielding, proper bypassing of power supplies, providing stable, low-noise power supplies, and the like. Cables and connections must be high quality and secure, as noise may be induced by environmental factors such as vibration and/or temperature fluctuation.

FIG. 2 shows the performance of a very low phase noise signal source, the Agilent E8254A generating a signal of 6.4 GHz, feeding different dividers, all set to divide by 64. This division ratio is achieved in the example of FIG. 1 by setting each of divide blocks 120 and 130 to divide by 8.

As will be understood by those familiar with the art, the noise level of the signal source dominates in the region up to approximately 100 KHz from the carrier; it is difficult to distinguish among the different dividers in this region.

Line 210 shows the phase noise performance of a commercially available high-performance divider such as the Agilent Technologies model 70429A Option K90 divider. This divider provides very good phase noise performance, on the order of −145 dBc/Hz. Line 220 shows the performance of a 70429A Option K90 divider under optimal operating conditions, dropping the phase noise outside 100 KHz to around −155 dBc/Hz. Line 230 shows the phase noise performance of a divider according to the present invention, producing phase noise values on the order of −160 dBc/Hz.

While the embodiments of the present invention have been illustrated in detail, it should be apparent that modifications and adaptations to these embodiments may occur to one skilled in the art without departing from the scope of the present invention as set forth in the following claims.

1. An improved frequency divider operating on a single-ended input signal comprising:
an input stage accepting the single-ended input signal and producing a differential output signal,
a differential divider for dividing the differential signal from the input stage and producing a differential output, and
a differential limiting amplifier amplifying the differential output signal from the differential divider and producing an output signal.

2. The improved divider of claim 1 where the differential divider comprises one or more differential divider blocks.

3. The improved divider of claim 2 where each divider block implements divide ratios of 1, 2, 4, 8, or 16.

4. The improved divider of claim 2 where one divider block implements a divide-by-N stage where N is an integer, followed by a divide-by-two stage.

5. The improved divider of claim 1 where the differential limiting amplifier produces a single-ended output.

6. The improved divider of claim 1 where the differential limiting amplifier produces complimentary outputs.

7. The improved divider of claim 1 where the input stage accepting the single-ended input signal and producing a differential output signal is integrated into the differential divider.

8. An improved method of providing frequency division to a single-ended electrical signal comprising:
converting the single-ended input signal to a differential signal,
dividing the differential signal converted from the single-ended input signal producing a divided differential output, and
amplifying the divided differential output using a differential limiting amplifier, producing an output signal.

9. The method of claim 8 where amplifying the divided differential output using a differential limiting amplifier produces a single-ended output signal.

10. The method of claim 8 where amplifying the divided differential output using a differential limiting amplifier produces complimentary output signals.

11. The method of claim 8 where the divide ratio includes 1 and integer powers of 2.

12. The method of claim 8 where the divide ratio includes a divide-by-N where N is an integer followed by a divide-by-two.
